(19) United States
(12) Patent Application Publication
(10) Pub. No.: US 2026/0221329 A1
(43) Pub. Date: Jul. 30, 2026

(54) COMMON MODE FILTER CIRCUIT WITH COOLER

(71) Applicant: IHI Corporation, Tokyo (JP)

(72) Inventor: Ryo HANEDA, Tokyo (JP)

(21) Appl. No.: 19/575,930

(22) Filed: Mar. 24, 2026

Related U.S. Application Data
(63) Continuation of application No. PCT/JP2024/036857, filed on Oct. 16, 2024.

(30) Foreign Application Priority Data
Dec. 19, 2023 (JP) 2023-213703

(51) Int. Cl. H01F 27/22; H01F 27/10; H01F 27/24; H01F 27/28; H01F 27/33; H03H 7/01

(52) U.S. Cl. CPC H01F 27/22; H01F 27/10; H01F 27/24; H01F 27/2823; H01F 27/33; H03H 7/0115

(57) ABSTRACT

A common mode filter circuit includes: a common mode transformer core having an opening, the common mode transformer core including, when facing the opening, a first side wall extending along a first direction and a second side wall extending along a second direction intersecting the first direction, the second side wall being longer than the first side wall; a primary conductive wire wound around the first side wall of the common mode transformer core; at least one secondary conductive wire inserted through the opening of the common mode transformer core; and a cooler joined to an outer peripheral surface of the second side wall.

### CROSS-REFERENCE TO RELATED APPLICATIONS

This application is a continuation application of PCT Application No. PCT/JP2024/036857, filed on October 16, 2024, which claims the benefit of priority from Japanese Patent Application No. 2023-213703, filed on December 19, 2023. The entire contents of the above listed PCT and priority applications are incorporated herein by reference.

### BACKGROUND

### FIELD

The present disclosure relates to a common mode filter circuit.

### DESCRIPTION OF THE RELATED ART

A common mode filter circuit may include an annular common mode transformer core through which a secondary winding is inserted inside, and a primary winding wound around the common mode transformer core so as to pass through an inside and an outside of the common mode transformer core (see International Publication No. 2022-118847).

### SUMMARY

An example common mode filter circuit may include: a common mode transformer core having an opening, the common mode transformer core including, when facing the opening, a first side wall extending along a first direction and a second side wall extending along a second direction intersecting the first direction, the second side wall being longer than the first side wall; a primary conductive wire wound around the first side wall of the common mode transformer core; at least one secondary conductive wire inserted through the opening of the common mode transformer core; and a cooler joined to an outer peripheral surface of the second side wall.

### BRIEF DESCRIPTION OF THE DRAWINGS

FIG. 1 illustrates an example common mode filter circuit.

FIG. 2A is a side view illustrating an example passive common noise canceller.

FIG. 2B is a view of the passive common noise canceller of FIG. 2A as viewed in the direction of arrow IIb.

FIG. 3 is a perspective view of an example common mode transformer included in the passive common noise canceller.

FIG. 4A is a side view illustrating another example passive common noise canceller.

FIG. 4B is a side view illustrating another example passive common noise canceller.

FIG. 4C is a side view illustrating another example passive common noise canceller.

FIG. 5A is a side view illustrating still another example passive common noise canceller.

FIG. 5B is a side view illustrating still another example passive common noise canceller.

FIG. 5C is a side view illustrating still another example passive common noise canceller.

### DETAILED DESCRIPTION

In the following description, with reference to the drawings, the same reference numbers are assigned to the same components or to similar components having the same function, and overlapping description is omitted.

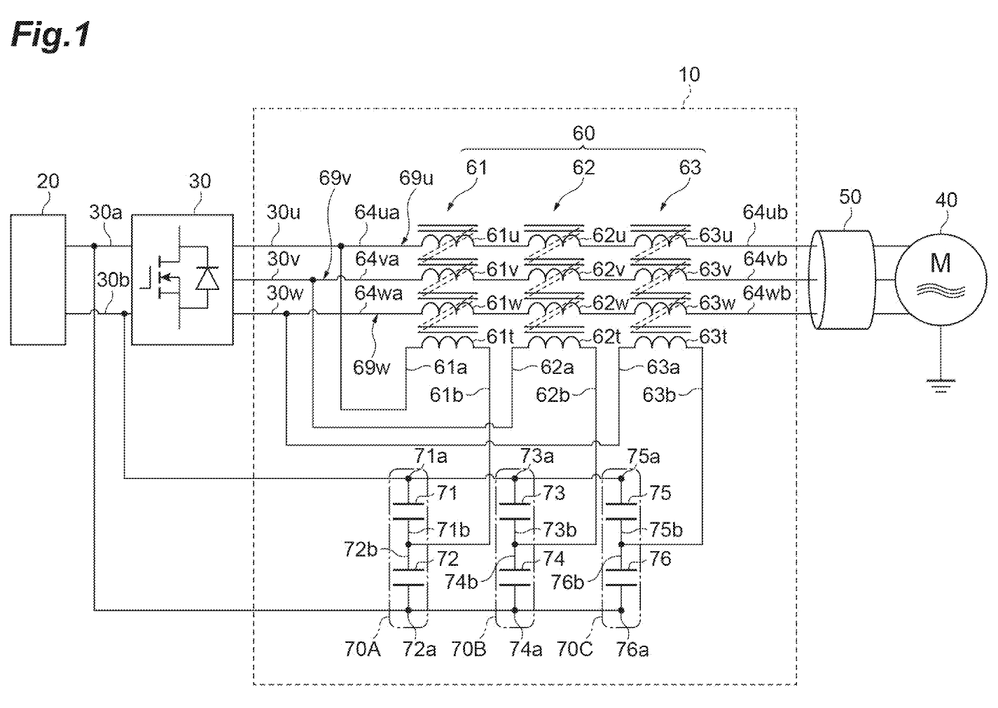

As shown in FIG. 1, the common mode filter circuit 10 is connected between an inverter 30 and a three-phase AC motor 40. The inverter 30 includes two input terminals 30a, 30b connected to a power supply 20, and three output terminals 30u, 30v, 30w that output three-phase AC. Three-phase AC is supplied to the three-phase AC motor 40 from the output terminals 30u, 30v, 30w of the inverter 30 via a motor cable 50. The output terminal 30u corresponds to a U-phase terminal. The output terminal 30v corresponds to a V-phase terminal. The output terminal 30w corresponds to a W-phase terminal.

The power supply 20 may be a DC power supply such as a battery and a converter. The inverter 30 may be a voltage source PWM inverter. The inverter 30 is configured to convert a DC voltage supplied from the power supply 20 via the input terminals 30a, 30b into a three-phase AC voltage by a switching operation of a power semiconductor element (IGBT, SiC, etc.). The inverter 30 is configured to output the three-phase AC voltage from the output terminals 30u, 30v, 30w. The AC voltage converted by the inverter 30 is supplied to the three-phase AC motor 40 via the common mode filter circuit 10 and the motor cable 50. A frame of the three-phase AC motor 40 is connected to a ground voltage via a grounding wire.

The common mode filter circuit 10 includes a passive common noise canceller 60. The passive common noise canceller 60 includes three common mode transformers 61, 62, 63 that cancel a common mode voltage of the three-phase AC. The common mode filter circuit 10 includes three pairs of capacitors 71, 72, 73, 74, 75, 76. The three pairs of capacitors 71, 72, 73, 74, 75, 76 are connected to the common mode transformers 61, 62, 63 and the input terminals 30a, 30b of the inverter 30, respectively.

The common mode filter circuit 10 may include three capacitor units 70A, 70B and 70C. The capacitor unit 70A may include two capacitors 71 and 72. The capacitor unit 70B may include two capacitors 73 and 74. The capacitor unit 70C may include two capacitors 75 and 76.

The common mode transformer 61 includes a one-phase primary winding (primary conductive wire) 61t and three-phase secondary windings (secondary conductive wires) 61u, 61v, 61w. The common mode transformer 62 includes a one-phase primary winding 62t and three-phase secondary windings 62u, 62v, 62w. The common mode transformer 63 includes a one-phase primary winding 63t and three-phase secondary windings 63u, 63v, 63w.

First ends 61a, 62a, 63a of the respective primary windings 61t, 62t, 63t of the three common mode transformers 61, 62, 63 are connected to the three output terminals 30u, 30v, 30w of the inverter 30, respectively. The first end 61a of the primary winding 61t of the common mode transformer 61 is connected to the three-phase U-phase output terminal 30u of the inverter 30. The first end 62a of the primary winding 62t of the common mode transformer 62 is connected to the three-phase V-phase output terminal 30v of the inverter 30. The one end 63a of the primary winding 63t of the common mode transformer 63 is connected to the three-phase W-phase output terminal 30w of the inverter 30.

The other ends 61b, 62b, 63b of the respective primary windings 61t, 62t, 63t of the three common mode transformers 61, 62, 63 are connected to second ends 71b, 73b, 75b of the capacitors 71, 73, 75. The capacitor 71 is one of a pair of capacitors 71, 72 among the three pairs of capacitors 71, 72, 73, 74, 75, 76. The capacitor 73 is one of a pair of capacitors 73, 74 among the three pairs of capacitors 71, 72, 73, 74, 75, 76. The capacitor 75 is one of a pair of capacitors 75, 76 among the three pairs of capacitors 71, 72, 73, 74, 75, 76. First ends 71a, 73a, 75a of the capacitors 71, 73, 75 are connected to the input terminal 30b which is one of the pair of input terminals 30a, 30b of the inverter 30.

The other ends 61b, 62b, 63b of the respective primary windings 61t, 62t, 63t of the three common mode transformers 61, 62, 63 are connected to the other ends 72b, 74b, 76b of the capacitors 72, 74, 76. The capacitor 72 is the other of the pair of capacitors 71, 72 among the three pairs of capacitors 71, 72, 73, 74, 75, 76. The capacitor 74 is the other of the pair of capacitors 73, 74 among the three pairs of capacitors 71, 72, 73, 74, 75, 76. The capacitor 76 is the other of the pair of capacitors 75, 76 among the three pairs of capacitors 71, 72, 73, 74, 75, 76. One ends 72a, 74a, 76a of the capacitors 72, 74, 76 are connected to the input terminal 30a which is the other of the pair of input terminals 30a, 30b of the inverter 30.

The other end 61b of the primary winding 61t of the common mode transformer 61 connected to the U-phase of the inverter 30 is connected to the other end 71b of the capacitor 71 and the other end 72b of the capacitor 72. The one end 71a of the capacitor 71 is connected to the one input terminal 30b of the inverter 30. The one end 72a of the capacitor 72 is connected to the other input terminal 30a of the inverter 30.

The other end 62b of the primary winding 62t of the common mode transformer 62 connected to the V-phase of the inverter 30 is connected to the other end 73b of the capacitor 73 and the other end 74b of the capacitor 74. The one end 73a of the capacitor 73 is connected to the one input terminal 30b of the inverter 30. The one end 74a of the capacitor 74 is connected to the other input terminal 30a of the inverter 30.

The other end 63b of the primary winding 63t of the common mode transformer 63 connected to the W-phase of the inverter 30 is connected to the other end 75b of the capacitor 75 and the other end 76b of the capacitor 76. The one end 75a of the capacitor 75 is connected to the one input terminal 30b of the inverter 30. The one end 76a of the capacitor 76 is connected to the other input terminal 30a of the inverter 30. The primary windings 61t, 62t, 63t and the capacitors 71, 72, 73, 74, 75, 76 constitute a filter that detects common mode voltages of the U-phase, V-phase, and W-phase.

The primary winding 61t and the capacitor unit 70A may constitute a filter that detects common mode voltages of the U-phase. The primary winding 62t and the capacitor unit 70B may constitute a filter that detects common mode voltages of the V-phase. The primary winding 63t and the capacitor unit 70C may constitute a filter that detects common mode voltages of the W-phase.

The three-phase secondary windings 61u, 61v, 61w, 62u, 62v, 62w, 63u, 63v, 63w of the three common mode transformers 61, 62, 63 are respectively connected in series with each other. First ends 64ua, 64va, 64wa of the respective three-phase secondary windings 61u, 61v, 61w, 62u, 62v, 62w, 63u, 63v, 63w of the three common mode transformers 61, 62, 63 connected in series with each other are connected to the three output terminals 30u, 30v, 30w of the inverter 30, respectively.

The other ends 64ub, 64vb, 64wb of the respective three-phase secondary windings 61u, 61v, 61w, 62u, 62v, 62w, 63u, 63v, 63w of the three common mode transformers 61, 62, 63 connected in series with each other are connected to respective phases of the three-phase AC motor 40 via the motor cable 50.

That is, the U-phase secondary windings 61u, 62u, 63u of the common mode transformers 61, 62, 63 are connected in series with each other. The one end 64ua of the secondary windings 61u, 62u, 63u is connected to the U-phase output terminal 30u of the inverter 30. The other end 64ub of the secondary windings 61u, 62u, 63u is connected to the U-phase of the three-phase AC motor 40.

The V-phase secondary windings 61v, 62v, 63v of the common mode transformers 61, 62, 63 are connected in series with each other. The one end 64va of the secondary windings 61v, 62v, 63v is connected to the V-phase output terminal 30v of the inverter 30. The other end 64vb of the secondary windings 61v, 62v, 63v is connected to the V-phase of the three-phase AC motor 40.

The W-phase secondary windings 61w, 62w, 63w of the common mode transformers 61, 62, 63 are connected in series with each other. The one end 64wa of the secondary windings 61w, 62w, 63w is connected to the W-phase output terminal 30w of the inverter 30. The other end 64wb of the secondary windings 61w, 62w, 63w is connected to the W-phase of the three-phase AC motor 40.

A ratio of the number of turns of the respective primary windings 61t, 62t, 63t of the three common mode transformers 61, 62, 63 to the number of turns of the secondary windings 61u, 61v, 61w, 62u, 62v, 62w, 63u, 63v, 63w may be 3:1. The number of turns of the respective primary windings 61t, 62t, 63t of the three common mode transformers 61, 62, 63 may be 3, and the number of turns of the respective secondary windings 61u, 61v, 61w, 62u, 62v, 62w, 63u, 63v, 63w of the three common mode transformers 61, 62, 63 may be 1 (only passing through the inside (opening) of a core 65 described later).

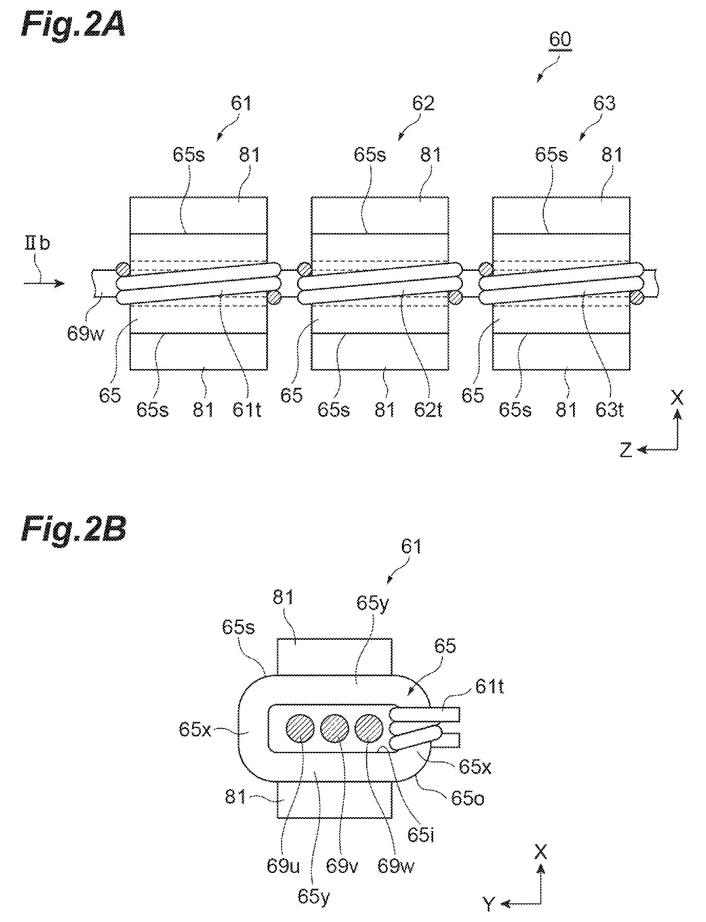

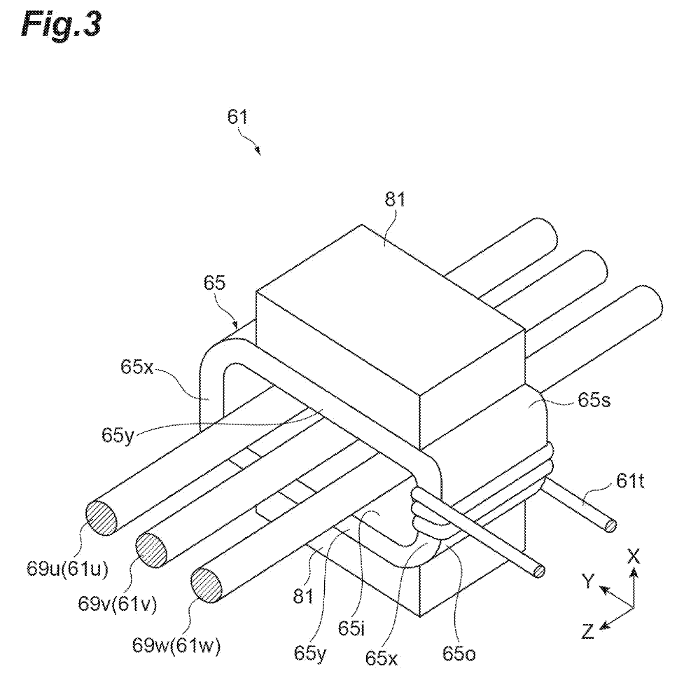

Hereinafter, the passive common noise canceller 60 will be further described with reference to FIGS. 2A, 2B and 3. As described above, the passive common noise canceller 60 includes the three common mode transformers 61, 62, 63. These three common mode transformers 61, 62, 63 have configurations similar to each other. Therefore, the common mode transformer 61 is shown as a representative in FIG. 3, and the configuration of the common mode transformer 61 will be described below as a representative, and overlapping descriptions of the common mode transformers 62, 63 may be omitted.

As shown in FIGS. 2 and 3, the common mode transformer 61 has an annular common mode transformer core 65 (simply referred to as "core 65" in this description) made of a magnetic material. The core 65 may be an iron core. The primary winding 61t of the common mode transformer 61 may be wound three times by passing through an inside 65i and an outside 65o of the core 65.

The secondary windings 61u, 61v, 61w of the common mode transformer 61 are each wound once by passing through the inside 65i (opening) of the core 65 (the space surrounded by the core 65) . Thus, a common mode transformer having a structure in which the secondary winding passes through the inside of the core only once may be generally referred to as a "through-type common mode transformer" or the like.

The primary winding 61t may be an electric wire. The primary winding 61t may be a conductive wire made of a metal with high electrical conductivity such as copper or aluminum covered with an insulating coating. The secondary windings 61u, 61v, 61w may be electric wires or busbars. The secondary windings 61u, 61v, 61w may be made of a material with high electrical conductivity such as copper or aluminum.

The common mode transformer 61 includes two heat sinks 81, 81 joined to the core 65. The heat sinks 81, 81 function as coolers for cooling the core 65. Details of the heat sinks 81, 81 will be described later.

In an example common mode filter circuit 10 shown in FIG. 1, the U-phase secondary winding 69u, the V-phase secondary winding 69v, and the W-phase secondary winding 69w pass through the insides 65i of the three cores 65 (the space surrounded by the core 65) of the common mode transformers 61, 62, 63 in order in the axial direction of the cores 65 (Z direction), respectively. The three cores 65 of the common mode transformers 61, 62, 63 are arranged in a straight line in the Z direction, and the secondary windings 69u, 69v, 69w extend linearly penetrating the three cores 65.

Of the secondary winding 69u, a portion passing through the common mode transformer 61 is the secondary winding 61u (FIG. 1), a portion passing through the common mode transformer 62 is the secondary winding 62u (FIG. 1), and a portion passing through the common mode transformer 63 is the secondary winding 63u (FIG. 1).

Similarly, of the secondary winding 69v, a portion passing through the common mode transformer 61 is the secondary winding 61v (FIG. 1), a portion passing through the common mode transformer 62 is the secondary winding 62v (FIG. 1), and a portion passing through the common mode transformer 63 is the secondary winding 63v (FIG. 1).

Similarly, of the secondary winding 69w, a portion passing through the common mode transformer 61 is the secondary winding 61w (FIG. 1), a portion passing through the common mode transformer 62 is the secondary winding 62w (FIG. 1), and a portion passing through the common mode transformer 63 is the secondary winding 63w (FIG. 1).

According to the common mode filter circuit 10 as described above, the common mode voltage that can cause bearing failure of the three-phase AC motor 40 is reduced.

In the common mode transformers 61, 62, 63 as described above, the temperature of the core 65 rises due to iron loss. Therefore, the common mode transformers 61, 62, 63 may include a configuration for cooling the core 65. Next, the configuration for cooling the core 65 in the passive common noise canceller 60 will be described.

The secondary windings 69u, 69v, 69w extend linearly within a range where the passive common noise canceller 60 is constructed. Further, as shown in FIGS. 2A, 2B and 3, the core 65 has a flattened tubular shape having a longitudinal direction and a transverse direction when viewed from an insertion direction of the secondary windings 69u, 69v, 69w. The core 65 extends in the insertion direction of the secondary windings 69u, 69v, 69w. The core 65 also extends in the axial direction thereof. In this disclosure, the insertion direction and the axial direction may be referred to as the Z direction.

The core 65 may be a rectangle with rounded corners (rounded rectangle) when viewed from the Z direction. The secondary windings 69u, 69v, 69w may be arranged in the longitudinal direction of the rounded rectangle, extend parallel to each other, and may pass through the inside 65i of the core 65. In this description, X, Y, and Z may be used to describe the positional relationship of each part, with the longitudinal direction of the rounded rectangle being the Y direction, the transverse direction being the X direction, and the insertion direction of the secondary windings 69u, 69v, 69w being the Z direction.

In the core 65 forming a rounded rectangle when viewed from the Z direction, there may be two portions extending linearly in the Y direction, two portions extending linearly in the X direction, and four rounded corner portions existing between these portions. In this description, a portion of the core 65 extending linearly in the Y direction when viewed from the Z direction may be referred to as a "core longitudinal portion" or "second side wall" and denoted by reference sign "65y". The core longitudinal portion 65y may be a flat plate-like portion having a thickness in the X direction and parallel to the YZ plane. A portion of the core 65 extending linearly in the X direction when viewed from the Z direction may be referred to as a "core transverse portion" or "first side wall" and denoted by reference sign "65x". The core transverse portion 65x is a flat plate-like portion having a thickness in the Y direction and parallel to the XZ plane.

The core 65 may include a pair of first side walls 65x and a pair of second side walls 65y. The first side walls 65x extend in a first direction when viewed from the Z direction. In this disclosure, the first direction may be referred to as an X direction. The first side walls 65x may have a flat plate shape having a thickness in the Y direction and extending along the XZ plane.

The second side walls 65y may extend in a second direction intersecting the first direction (the X direction), when viewed from the Z direction. In this disclosure, the second direction may be referred to as a Y direction. The second side walls 65y may have a flat plate shape having a thickness in the X direction and extending along the YZ plane. The second side walls 65y may be longer than the first side walls 65x.

The pair of first side walls 65x may be arranged substantially parallel to each other so as to face each other in the Y direction. The pair of second side walls 65y may be arranged substantially parallel to each other so as to face each other in the X direction. The secondary windings 69u, 69v, 69w may be arranged in the Y direction when viewed from the Z direction so as to extend parallel to each other in the Z direction.

The common mode transformer 61 includes two heat sinks 81, 81 joined to the core 65 in order to cool the core 65. The two heat sinks 81, 81 are arranged so as to sandwich the core 65 therebetween in the X direction and are provided so as to project from the core 65 in the X direction. The heat sinks 81 and the core 65 are joined such that a surface of the heat sinks 81 and an outer peripheral surface 65s of the core 65 are in close contact. The heat sinks 81 may be made of a material with high thermal conductivity such as copper or aluminum. The heat sinks 81 are configured to exchange heat with the joined core 65. A joining method of the heat sinks 81 and the core 65 may be adhesion using an adhesive. A heat conduction portion (not shown) made of a thermally conductive material (TIM: Thermal Interface Material) may be interposed between the heat sinks 81 and the core 65. The heat sinks 81, 81 are electrically insulated from the primary winding 61t and the secondary windings 69u, 69v, 69w.

The heat sinks 81 may form a rectangular parallelepiped and be joined to the outer peripheral surface 65s in the second side walls 65y. Dimensions of the heat sinks 81 in the Y direction and the Z direction may be substantially equal to dimensions of the second side walls 65y in the Y direction and the Z direction. The heat sinks 81 may be provided over substantially the entirety of the second side walls 65y.

The dimensions of the heat sinks 81 in the Y direction and the Z direction may be larger or smaller than the dimensions of the second side walls 65y in the Y direction and the Z direction. When the dimension of the heat sinks 81 in the Y direction is larger than that of the second side walls 65y, both ends of the heat sinks 81 in the Y direction may protrude from the second side walls 65y in the Y direction. In this case, there may be a gap in the X direction between the protruding portion and the rounded corner portion of the core 65.

The heat sinks 81 may be respectively joined to the second side walls 65y of the core 65 of the common mode transformer 61. The common mode transformer 61 may include the core 65 and the two heat sinks 81, 81 arranged with the core 65 sandwiched therebetween.

The primary winding 61t of the common mode transformer 61 is wound around one of the pair of first side walls 65x. The primary winding 61t may be wound three times around the one of the pair of first side walls 65x so as to alternately pass through the inside 65i and the outside 65o of the core 65. The primary winding 61t does not interfere with the heat sinks 81 arranged on the second side walls 65y. The primary winding 61t may be wound around the one of the pair of first side walls 65x at a position aligned in the Y direction with respect to the secondary windings 69u, 69v, 69w. The primary winding 61t and the secondary windings 69u, 69v, 69w may be arranged along the Y direction. Thus, the common mode transformer 61 can be made compact by an arrangement in which the secondary windings 69u, 69v, 69w are arranged in the Y direction and pass through the inside 65i of the core 65, and a winding portion of the primary winding 61t is located at a position aligned in the Y direction with respect to the secondary windings 69u, 69v, 69w.

The passive common noise canceller 60 includes the three common mode transformers 61, 62, 63 having the above configuration, and the three common mode transformers 61, 62, 63 are arranged in the Z direction.

FIGS. 2A, 2B, and 3 may not show the exact shape or dimensions of each part. Although the heat sinks 81 are schematically illustrated as a relatively simple rectangular parallelepiped in FIGS. 2A, 2B, and 3, the heat sinks 81 may have a large number of thin plate-like parallel fins. A heat sink having such a large number of fins may be generally referred to as a "comb-shaped heat sink". The heat sinks 81 may be a hollow member having a hollow portion through which a refrigerant (for example, cooling air or cooling water) passes.

In the common mode transformers 61, 62, 63, the heat sinks 81, 81 joined to the core 65 exchange heat with the core 65. The heat of the core 65 that has become high temperature is transferred to the heat sinks 81, 81. Then, the core 65 is cooled by dissipating the heat transferred from the core 65 to the outside from the heat sinks 81, 81. A method of heat dissipation from the heat sinks 81, 81 to the outside (a method of cooling the heat sinks 81, 81) may be a natural air cooling, a forced air cooling, or a water cooling. A cooling unit that cools the heat sinks 81, 81 by any of the methods as described above may be provided in an apparatus in which the common mode filter circuit 10 is constructed. The heat sinks 81 may be designed according to specifications of the cooling unit. For example, when the cooling unit is a blower and the heat sinks 81 are comb-shaped, the heat sinks 81 may be designed such that the direction of the fins of the heat sinks 81 is parallel to a flow direction of cooling air by the cooling unit.

Thus, according to the common mode filter circuit 10, the core 65 can be cooled. Then, by designing the cooling capacity of the heat sinks 81, 81, the temperature of the core 65 may be within an allowable upper limit.

It is to be understood that not all aspects, advantages and features described herein may necessarily be achieved by, or included in, any one particular example. Indeed, having described and illustrated various examples herein, it should be apparent that other examples may be modified in arrangement and detail.

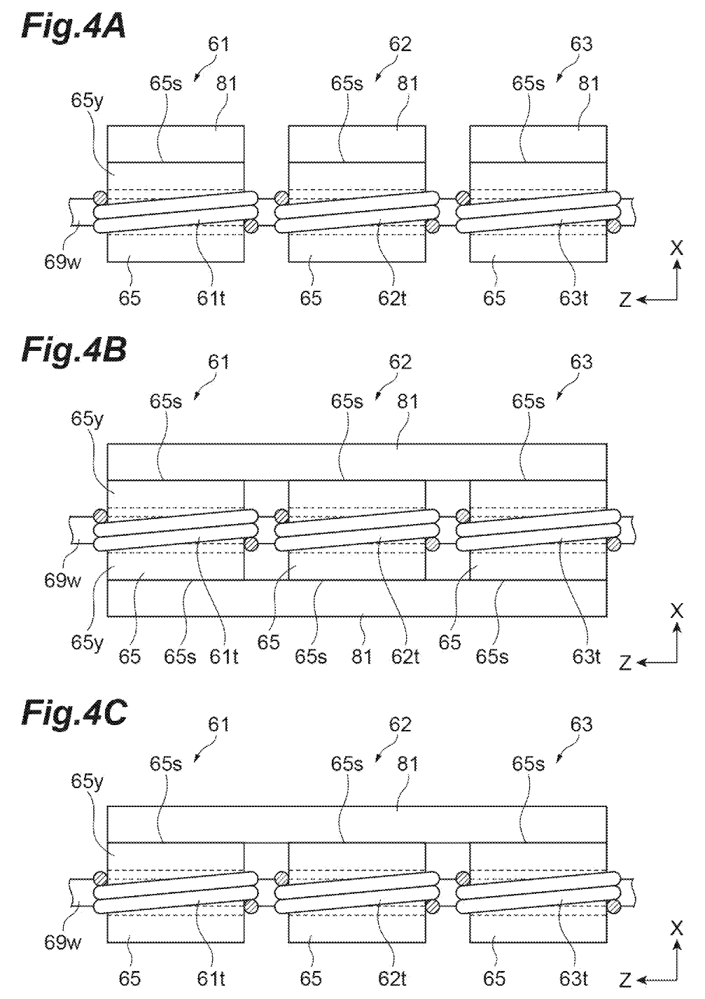

As shown in FIG. 4A, the heat sink 81 may be joined to either one of the pair of second side walls 65y in each common mode transformer 61, 62, 63.

As shown in FIG. 4B, the heat sinks 81, 81 joined to the three cores 65 of the respective common mode transformers 61, 62, 63 may be respectively integrally shared. One of the heat sinks 81, 81 may be joined to one of the pair of second side walls 65y of the respective common mode transformers 61, 62, 63, and the other of the heat sinks 81, 81 may be joined to the other of the pair of second side walls 65y of the respective common mode transformers 61, 62, 63. In this case, one heat sink 81 may be extended to a length of three or more times the dimension of the core 65 in the Z direction, and may be joined to the core longitudinal portions 65y of the three cores 65. The number of parts can be reduced by such sharing of the heat sink 81. As shown in FIG. 4C, the heat sink 81 may be provided only on one core longitudinal portion 65y of each core 65. A single heat sink 81 is joined to one of the pair of second side walls 65y of the common mode transformers 61, 62, and 63, and no other heat sink may be joined to the other of the pair of second side walls 65y of the common mode transformers 61, 62, and 63.

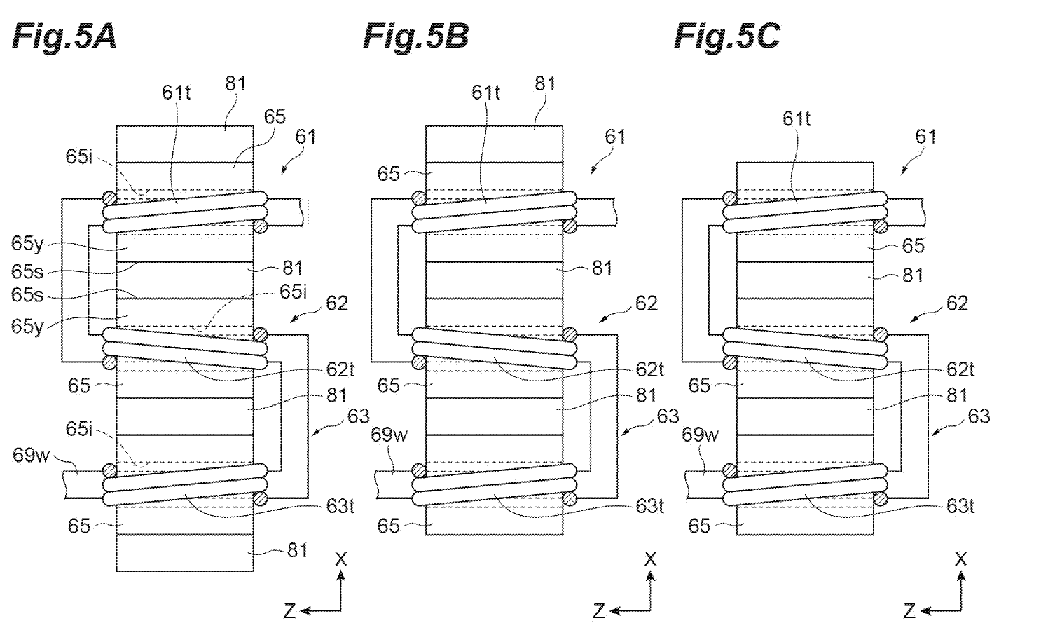

As shown in FIG. 5A, the three common mode transformers 61, 62, 63 may be arranged in the X direction. In this case, in order to pass through the insides 65i of the three respective cores 65 in order, the secondary windings 69u, 69v, 69w may be laid in an S-shaped path. In this case, in the core 65 of the common mode transformers 61, 63 and the core 65 of the common mode transformer 62, passing directions of the secondary windings 69u, 69v, 69w may be opposite. Correspondingly, in the primary windings 61t, 63t of the common mode transformers 61, 63 and the primary winding 62t of the common mode transformer 62, winding directions with respect to the core 65 may be opposite. Passing directions of the three secondary windings 69u, 69v, 69w with respect to one core 65 are all the same. As shown in FIG. 5A, the heat sink 81 between the cores 65 adjacent to each other in the X direction is integrally shared. Both opposing surfaces of one shared heat sink 81 are respectively joined to the outer peripheral surfaces 65s of the core longitudinal portions 65y of the two cores 65. One of the pair of outer surfaces of the heat sink 81 may be joined to the outer peripheral surface 65s of one of the two cores 65 adjacent to each other in the X direction, and the other of the pair of outer surfaces of the heat sink 81 may be joined to the outer peripheral surface 65s of the other of the two cores 65 adjacent to each other in the X direction. The three cores 65 and the four heat sinks 81 may be alternately arranged in the X direction in a state of being joined in order. The number of parts can be reduced by such sharing of the heat sinks 81.

In the configuration in which the cores 65 and the heat sinks 81 are alternately arranged as described above, the heat sink 81 at one end of the arrangement may be omitted as shown in FIG. 5B. In this case, the three cores 65 and the three heat sinks 81 may be alternately arranged. The heat sinks 81 at both ends of the arrangement may be omitted as shown in FIG. 5C. In this case, the three cores 65 and the two heat sinks 81 may be alternately arranged.

The shape of the core 65 is not limited to one having a cross section of a rounded rectangle as long as it is an annular shape allowing inserting of the secondary windings 69u, 69v, 69w and having a flat cross section. For example, the shape of the core 65 or the heat sink 81 may be an annular shape forming an ellipse when viewed from the Z direction, an annular shape forming a rectangle, or an oval shape. In this case, the heat sink 81 may be joined to the outer peripheral surface 65s of the second side wall 65y. The primary winding 61t may be wound around the outer peripheral surface 65s of the first side wall 65x so as not to interfere with the heat sinks 81. When the outer peripheral surface 65s is not a flat surface but a curved surface in the second side wall 65y, a joining surface of the heat sink 81 may be formed according to the curved shape of the curved surface.

The secondary windings 69u, 69v, 69w may be electric wires or busbars as described above. There is no restriction on how to arrange the three secondary windings 69u, 69v, 69w, as long as they are inserted inside the core 65. The secondary windings 69u, 69v, 69w may extend linearly or may be bent.

The core 65 and the heat sinks 81 are not limited to integrally formed members, and may be composed of a plurality of parts divided in a circumferential direction.

An example common mode filter circuit may include: a common mode transformer core having an opening, the common mode transformer core including, when facing the opening, a first side wall extending along a first direction and a second side wall extending along a second direction intersecting the first direction, the second side wall being longer than the first side wall; a primary conductive wire wound around the first side wall of the common mode transformer core; at least one secondary conductive wire inserted through the opening of the common mode transformer core; and a cooler joined to an outer peripheral surface of the second side wall.

In some examples, the at least one secondary conductive wire may include a plurality of secondary conductive wires. The plurality of secondary conductive wires may be arranged along the second direction.

In some examples, the primary conductive wire and the plurality of secondary conductive wires may be arranged along the second direction.

An example common mode filter circuit may further include a second common mode transformer core having a second opening. The common mode transformer core and the second common mode transformer core may be arranged such that the opening of the common mode transformer core and the second opening of the second common mode transformer core face each other. The cooler may be joined to the outer peripheral surface of the second side wall of the common mode transformer core and an outer peripheral surface of the second common mode transformer core, and be thermally coupled with both the common mode transformer core and the second common mode transformer core.

An example common mode filter circuit may further include a second common mode transformer core having a second opening. The common mode transformer core and the second common mode transformer core may be arranged along the first direction. The cooler may be located between the common mode transformer core and the second common mode transformer core, and be thermally coupled with both the common mode transformer core and the second common mode transformer core.

In some examples, the at least one secondary conductive wire may pass through both the opening of the common mode transformer core and the second opening of the second common mode transformer core.

An example common mode filter circuit may further include a second primary conductive wire wound around an outer peripheral surface of the second common mode transformer core. A winding direction of the primary conductive wire may be opposite to a winding direction of the second primary conductive wire.

In some examples, a ratio of a number of turns of the primary conductive wire to a number of turns of the at least one secondary conductive wire may be 3:1.

In some examples, the cooler may include a plurality of fins.

In some examples, the cooler may have a flow path configured to allow coolant to pass therethrough.

An example common mode transformer may include: a common mode transformer core having an opening, the common mode transformer core including, when facing the opening, a first side wall extending along a first direction, and a second side wall extending along a second direction intersecting the first direction, the second side wall being longer than the first side wall; and a cooler joined to an outer peripheral surface of the second side wall.

An example passive common noise canceller may include: the common mode transformer; and a second common mode transformer core including a second opening, when facing the second opening, a third side wall extending along the first direction, and a fourth side wall extending along the second direction, the fourth side wall being longer than the third side wall. The cooler may be joined to both an outer peripheral surface of the second side wall of the common mode transformer core and an outer peripheral surface of the fourth side wall of the second common mode transformer core.

In some examples, the cooler may be thermally coupled with both the common mode transformer core and the second common mode transformer core.

An example passive common noise canceller may further include a conductive wire inserted through both the opening of the common mode transformer core and the second opening of the second common mode transformer core.

An example passive common noise canceller may further include: a first conductive wire wound around an outer peripheral surface of the first side wall; and a second conductive wire wound around an outer peripheral surface of the third side wall.

In some examples, the common mode transformer core and the second common mode transformer core may be arranged such that the opening of the common mode transformer core and the second opening of the second common mode transformer core face each other. The first conductive wire and the second conductive wire may be arranged so as to overlap each other when facing the opening and the second opening.

In some examples, the common mode transformer core and the second common mode transformer core may be arranged along the first direction. The first conductive wire and the second conductive wire may be arranged along the first direction so as to overlap each other when viewed from the first direction.

In some examples, a winding direction of the first conductive wire may be opposite to a winding direction of the second conductive wire.

What is claimed is:

1. A common mode filter circuit comprising:
a common mode transformer core having an opening, the common mode transformer core including, when facing the opening, a first side wall extending along a first direction and a second side wall extending along a second direction intersecting the first direction, the second side wall being longer than the first side wall;
a primary conductive wire wound around the first side wall of the common mode transformer core;
at least one secondary conductive wire inserted through the opening of the common mode transformer core; and
a cooler joined to an outer peripheral surface of the second side wall.

2. The common mode filter circuit according to claim 1,
wherein the at least one secondary conductive wire comprises a plurality of secondary conductive wires, and
wherein the plurality of secondary conductive wires are arranged along the second direction.

3. The common mode filter circuit according to claim 2, wherein the primary conductive wire and the plurality of secondary conductive wires are arranged along the second direction.

4. The common mode filter circuit according to claim 1, further comprising a second common mode transformer core having a second opening,
wherein the common mode transformer core and the second common mode transformer core are arranged such that the opening of the common mode transformer core and the second opening of the second common mode transformer core face each other, and
wherein the cooler is joined to the outer peripheral surface of the second side wall of the common mode transformer core and an outer peripheral surface of the second common mode transformer core, and is thermally coupled with both the common mode transformer core and the second common mode transformer core.

5. The common mode filter circuit according to claim 1, further comprising a second common mode transformer core having a second opening,
wherein the common mode transformer core and the second common mode transformer core are arranged along the first direction, and
wherein the cooler is located between the common mode transformer core and the second common mode transformer core, and is thermally coupled with both the common mode transformer core and the second common mode transformer core.

6. The common mode filter circuit according to claim 5, wherein the at least one secondary conductive wire passes through both the opening of the common mode transformer core and the second opening of the second common mode transformer core.

7. The common mode filter circuit according to claim 6, further comprising a second primary conductive wire wound around an outer peripheral surface of the second common mode transformer core,
wherein a winding direction of the primary conductive wire is opposite to a winding direction of the second primary conductive wire.

8. The common mode filter circuit according to claim 1, wherein a ratio of a number of turns of the primary conductive wire to a number of turns of the at least one secondary conductive wire is 3:1.

9. The common mode filter circuit according to claim 1, wherein the cooler includes a plurality of fins.

10. The common mode filter circuit according to claim 1, wherein the cooler has a flow path configured to allow coolant to pass therethrough.

11. A common mode transformer comprising:
a common mode transformer core having an opening, the common mode transformer core including, when facing the opening, a first side wall extending along a first direction, and a second side wall extending along a second direction intersecting the first direction, the second side wall being longer than the first side wall; and
a cooler joined to an outer peripheral surface of the second side wall.

12. A passive common noise canceller comprising:
the common mode transformer according to claim 11; and
a second common mode transformer core including a second opening, when facing the second opening, a third side wall extending along the first direction, and a fourth side wall extending along the second direction, the fourth side wall being longer than the third side wall,
wherein the cooler is joined to both an outer peripheral surface of the second side wall of the common mode transformer core and an outer peripheral surface of the fourth side wall of the second common mode transformer core.

13. The passive common noise canceller according to claim 12, wherein the cooler is thermally coupled with both the common mode transformer core and the second common mode transformer core.

14. The passive common noise canceller according to claim 12, further comprising a conductive wire inserted through both the opening of the common mode transformer core and the second opening of the second common mode transformer core.

15. The passive common noise canceller according to claim 12, further comprising:
a first conductive wire wound around an outer peripheral surface of the first side wall; and
a second conductive wire wound around an outer peripheral surface of the third side wall.

16. The passive common noise canceller according to claim 15,
wherein the common mode transformer core and the second common mode transformer core are arranged such that the opening of the common mode transformer core and the second opening of the second common mode transformer core face each other, and
wherein the first conductive wire and the second conductive wire are arranged so as to overlap each other when facing the opening and the second opening.

17. The passive common noise canceller according to claim 15,
wherein the common mode transformer core and the second common mode transformer core are arranged along the first direction, and
wherein the first conductive wire and the second conductive wire are arranged along the first direction so as to overlap each other when viewed from the first direction.

18. The passive common noise canceller according to claim 17, wherein a winding direction of the first conductive wire is opposite to a winding direction of the second conductive wire.
